(19) United States
(12) Patent Application Publication
(10) Pub. No.: US 2025/0311138 A1
(43) Pub. Date: Oct. 2, 2025

(54) Integrated PON chassis architecture for data center networks

(71) Applicant: Ciena Corporation, Hanover, MD (US)

(72) Inventors: Sujit Ghosh, Gurgaon (IN); Sachin Singla, Gurgaon (IN); Karan Goel, Gurugram (IN); Sardeep Heda, Gurgaon (IN)

(73) Assignee: Ciena Corporation, Hanover, MD (US)

(21) Appl. No.: 18/659,341

(22) Filed: May 9, 2024

(30) Foreign Application Priority Data
Mar. 27, 2024 (IN) 202411024343

(51) Int. Cl. H05K 7/14; G02B 6/44

(52) U.S. Cl. CPC H05K 7/1452; G02B 6/4446; G02B 6/4452; H05K 7/1488

(57) ABSTRACT

An integrated Passive Optical Network (PON) chassis architecture is provided for data center networks. The chassis includes a housing configured to connect on top of a rack; a plurality of modules that are selectively insertable in the housing, each of the plurality of modules supporting one or more Optical Network Units (ONUs) or Optical Network Terminals (ONTs) for operation in a Passive Optical Network (PON); and a fiber splitter configured to optically connect to each of the plurality of modules and to a PON distribution network that connects to one or more Optical Line Terminals (OLTs).

### FIELD OF THE DISCLOSURE

The present disclosure relates generally to networking and computing. More particularly, the present disclosure relates to systems and methods for an integrated Passive Optical Network (PON) chassis architecture for data center networks.

### BACKGROUND OF THE DISCLOSURE

Data centers are physically organized into racks, which house servers, storage units, network devices, and the like. Each rack typically supports a standardized size (19 inches wide) but can vary in height, expressed in rack units (RU). A data center network provides connectivity between the devices in the racks. For example, these devices can be generally referred to as rack servers or simply servers, providing some compute and/or storage resources. In the racks, there are also switches for interconnecting the rack servers. Generally, the switches can be placed at the top of the rack (i.e., Top of Rack (ToR) switches), at the end of a row of racks (i.e., End of Row (EoR) switches), and the like. Of course, as network connectivity and computing resources continue to proliferate, data centers continue to grow in size and scale. Cloud providers and other Internet providers continue to deploy more and more rack servers and switches using either the ToR or EoR approaches.

### BRIEF SUMMARY OF THE DISCLOSURE

The present disclosure relates to systems and methods for an integrated PON chassis architecture for data center networks. The integrated PON chassis architecture is used to replace the ToR or EoR approaches for data center networks, supporting server to switch connectivity. Optical Network Units (ONUs) or Optical Network Terminals (ONTs) are used to interconnect each rack server to a switch via an Optical Line Terminal (OLT), using a PON architecture inside the data center. That is, the PON architecture is used within the data center for network connectivity therein. Advantageously, the ONUs replace existing ToR or EoR switches, thereby saving rack space and not requiring extensive cabling. This provides improvements in space, power consumption, installation, and cost. The present disclosure includes a compact, low cost, small size, low power, etc. chassis that is used to house ONUs for server connectivity. Advantageously, the chassis is designed to mount to the top of a rack, i.e., the literal top of the rack, so as to avoid taking any valuable rack space for servers.

In an embodiment, a chassis includes a housing configured to connect on top of a rack; a plurality of modules that are selectively insertable in the housing, each of the plurality of modules supporting one Optical Network Unit (ONU) or Optical Network Terminal (ONT) for operation in a Passive Optical Network (PON); a plurality of modules that are selectively insertable in the housing, each of the plurality of modules supporting one console server; and a fiber splitter configured to optically connect to each of the plurality of ONU modules and to a PON distribution network that connects to one or more Optical Line Terminals (OLTs). The ONU module includes one or more Ethernet ports and the Console Server module includes one or more RS-232 ports for connecting to a plurality of devices in the rack.

The housing includes a power backplane configured to connect to a power supply and to provide power to the plurality of modules. The housing can include a flange configured to attach to the top of the rack. The top of the rack is above a plurality of servers mounted inside the rack.

The fiber splitter includes N:M optical ports, with N optical ports communicatively connected to the one or more OLTs and M optical ports communicatively connected to corresponding optical ports on the plurality of modules. The N optical ports can be connected to a second fiber splitter associated with one or more rows of racks with the second fiber splitter communicatively connected to the one or more OLTs. The housing can be air cooled via a plurality of openings enabling airflow, and wherein the chassis includes a fanless design. The chassis can further include one or more cable routing guides connected to a front of the housing, wherein the rack includes one or more openings for cabling from devices mounted therein to the plurality of modules.

In another embodiment, a data center network includes X Optical Network Units (ONUs) or Optical Network Terminals (ONTs), X is an integer greater than one, each ONU or ONT is contained in a corresponding chassis that is configured to connect on top of a rack, and each ONU or ONT is configured to connect to a corresponding server in the associated rack; Y Optical Line Terminals (OLTs), Y is an integer greater than or equal to one; and a Passive Optical Network (PON) distribution network including one or more fiber splitters, the PON distribution network optical connects each of the X ONUs or ONTs to the Y OLTs. The top of the rack is above a plurality of servers mounted inside the rack.

Each corresponding chassis can include a plurality of modules that connect to a plurality of servers mounted inside the rack, and an optical connection that connects to the PON distribution network from the rack. The X ONUs or ONTs with the Y OLTs operate in lieu of a Top of Rack (ToR) data center network and an End of Rack (EoR) data center network. The X ONUs or ONTs utilize PON techniques to connect the corresponding server to a carrier network for out-of-band management of data center servers/devices. The value of X can be selected based on bandwidth requirements of a plurality of servers in the data center network. The corresponding chassis can include a housing configured to connect on top of the rack; a plurality of modules that are selectively insertable in the housing, each of the plurality of modules supporting one of the X ONUs or ONTs; a plurality of modules that are selectively insertable in the housing, each of the plurality of modules supporting one of the console servers; and a fiber splitter of the one or more fiber splitters. Each of the plurality of ONU modules can include one or more Ethernet ports, each configured to connect to a device in the rack; and an optical port configured to connect to the fiber splitter. Each of the plurality of console server modules can include one or more RS-232 ports, each configured to connect to a device in the rack.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a block diagram of a ToR data center network with servers interconnected to ToR switches which interconnect to an aggregation switch.

FIG. 2 is a block diagram of an EoR data center network with the servers interconnected to an EoR switch.

FIG. 3 is a block diagram of a PON data center network with the servers interconnected to an ONU chassis that contains multiple ONUs and which is integrated on a canopy of the rack, without taking rack space.

FIG. 4 is a perspective diagram of the ONU chassis and on a canopy of the rack along with a detailed view of the ONU chassis.

FIG. 5 is a close-up perspective diagram of the top of the rack with the ONU chassis thereon.

FIG. 6 is a front view of the ONU chassis.

FIG. 7 is a rear view of the ONU chassis.

FIG. 8 is an exploded view of a housing of the ONU chassis.

FIG. 9 is a perspective diagram of an ONU module.

FIG. 10 is a front view of the ONU module.

FIG. 11 is a rear view of the ONU module.

FIG. 12 is a perspective diagram of a console module.

FIG. 13 is a front view of the console module.

FIG. 14 is a rear view of the console module.

FIG. 15 is a perspective diagram of a fiber splitter.

FIG. 16 is a front view of the fiber splitter.

### DETAILED DESCRIPTION OF THE DISCLOSURE

Again, the present disclosure relates to systems and methods for an integrated PON chassis architecture for data center networks.

### Conventional Data Center Networks

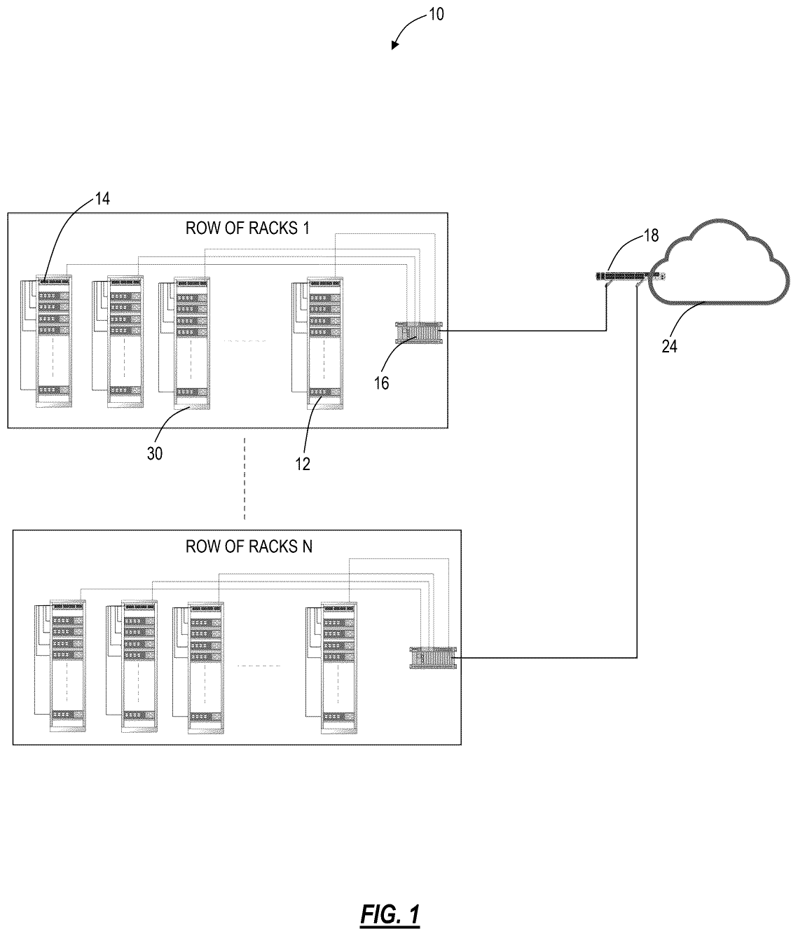

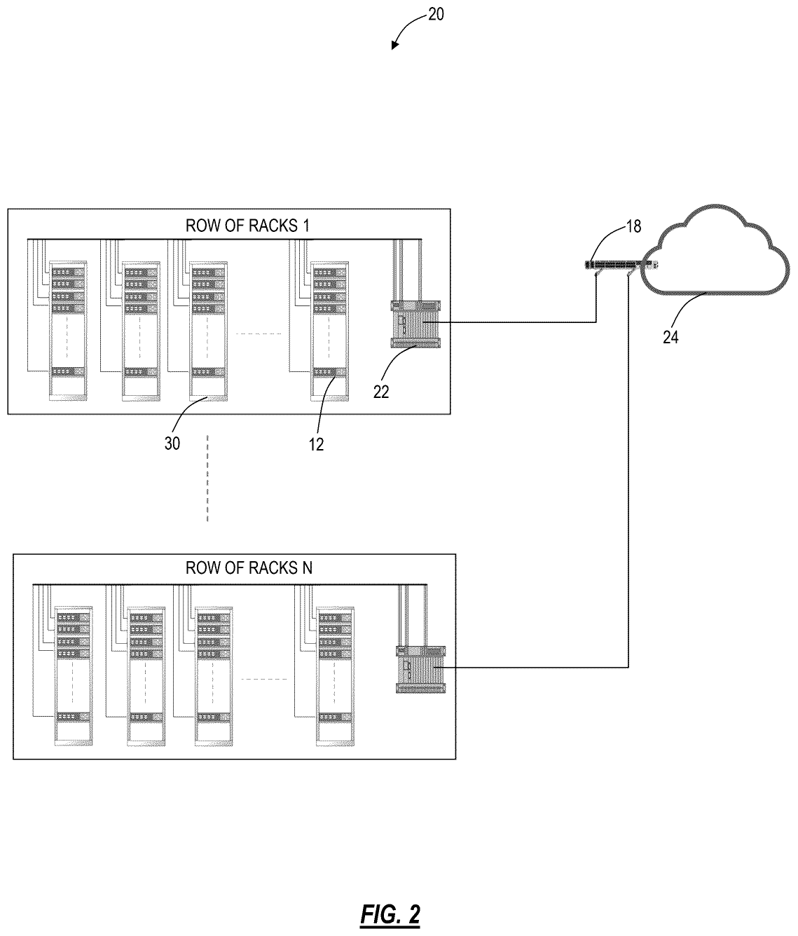

FIG. 1 is a block diagram of a ToR data center network 10 with servers 12 interconnected to ToR switches 14. Here, there are N rows of racks and each ToR switch 14 connects to a switch 16 which connects to an aggregation switch/router 18. FIG. 2 is a block diagram of an EoR data center network 20 with the servers 12 interconnected to an EoR switch 22. Each EoR switch connects to the switch/router 18. The aggregation switch/router 18 can connect to a carrier network 24, providing connectivity to the data center and the associated servers 12.

In both the networks 10, 20, there are racks 30 which physically house the servers 12 and the switches 14, 16, 18, 22. There are tradeoffs and drawbacks of either of these approaches including:
(1) The ToR data center network 10 consumes rack space resulting in more racks to meet the required capacity. Because of the numerous switches 14, 16, this is also complex to manage, consumes more power, and requires additional cooling.
(2) The EoR data center network 20 requires fewer switches however it requires a large number of cables resulting in high cost of cables and also becomes expensive to manage and upgrade to future bandwidth requirements.

Additionally, both the ToR and EoR approaches use Active Ethernet for server to switch connections. Active Ethernet requires forced cooling due to its higher power consumption, and also requires rack space.

The existing ToR data center network 10 uses 1 RU switch per rack (e.g., a 48-port router/switch per rack), and there are hundreds to thousands of racks in a data center. The EoR data center network 20 reduces the 1 RU switch per rack, but still requires a larger switch/router 18 at the end of the row, which is contained in a rack, taking up to half of the rack 30 or more. In addition to the wasted rack space, these approaches require significant overhead and management.

### PON Network Architecture

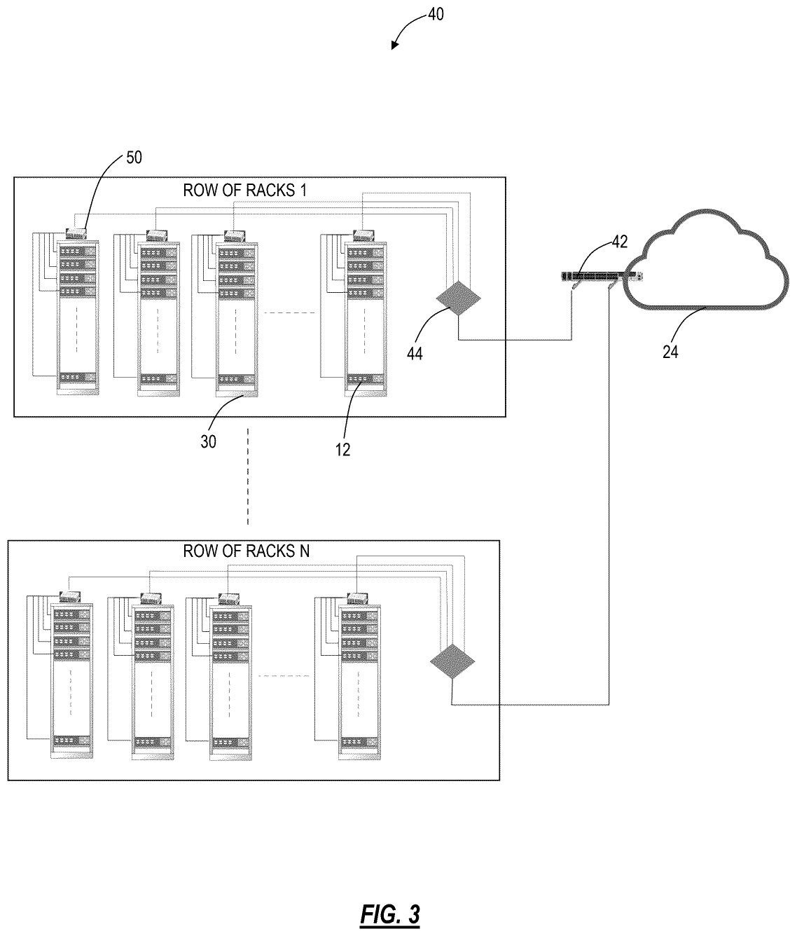

FIG. 3 is a block diagram of a PON data center network 40 with the servers 12 interconnected to an ONU chassis 50 that contains multiple ONUs, and which is integrated on the rack 30, without taking rack space. The present disclosure includes adaptation of a PON network architecture to the internal data center network, namely in place of the ToR data center network 10 or the EoR data center network 20. The PON network architecture includes a plurality of ONUs, in the ONU chassis 50, that all connect to an OLT 42 via a fiber splitter 44. The OLT 42 is a switch that aggregates all of the ONUs, and the OLT 42 can be located next to the fiber splitter 44.

There are generally two tracks of PON standards—Gigabit Passive Optical Network (GPON) and Ethernet Passive Optical Network (EPON), also known as Gigabit Ethernet Passive Optical Network (GEPON). GPON is defined by the ITU-T through a series of G.984.x standards, whereas EPON is defined by the IEEE as part of the Ethernet standard, specifically under the 802.3ah specification. Note, ONU is an IEEE term, whereas Optical Network Terminal (ONT) is an ITU-T term. The present disclosure utilizes ONU for the ONUs, but those skilled in the art will appreciate the present disclosure contemplates operation with GPON, EPON, etc.

In a typical deployment, the ONUs are located in the field, at subscriber locations, e.g., homes. Here, the individual ONUs are connected to subscriber equipment via Ethernet and optically connected to the OLT via various splitters forming a tree network, i.e., one OLT to many ONUs. The present disclosure contemplates using the ONUs to connect to the servers 12. That is, the PON architecture is used internally in the data center network. Of note, the ONUs are deployed in the ONU chassis 50 which is integrated with the rack 30, namely the integrated PON chassis architecture. Each ONU module 60 in the ONU chassis 50 can have one or more Ethernet ports to connect to one or more servers 12 in the rack 30. In an example embodiment, each ONU module 60 includes four Ethernet ports, so one ONU module 60 can connect to four servers 12, distributing traffic from an example 10 G PON into four Ethernet User Network Interface (UNI) ports.

The ONU chassis 50 is used in the racks 30, with the servers 12 to leverage the benefits of PON technology to overcome the disadvantages of ToR and EoR approaches, namely rack space, cooling, power consumption, complexity, and active Ethernet cabling. In particular, the ONU chassis 50 can mount to the literal top of the rack, i.e., not taking up any RUs in the rack. That is, the ONU chassis 50 is mounted on the top of the rack 30, but unlike the ToR switch 14, it does not take up any rack space, i.e., RUs in the rack. The ONU chassis 50 includes a novel, field replacement approach for individual ONUs, requires less power than Active Ethernet approaches (e.g., around 50% less), etc. Also, the ONUs are easy to install, cost effective, and the like, based on the ONU chassis 50 design provided herein.

Data center operators are looking for a zero RU solution. The PON data center network 40 offers such a solution. Compared to the ToR data center network 10 or the EoR data center network 20, the PON data center network 40 reduces operational complexity, reduces a number of internal data center fibers (e.g., such as from a central location or office to each row of racks 30), and removes the aggregation switch 14, 16, 22, by using the fiber splitter.

A typical 48-port Ethernet switch has only Ethernet ports. Data center management can require other ports, such as a serial port, for Out-of-Band (OoB) management. The 48-port Ethernet switch does not have RS-232 serial port that can be used to provide another connection to the server's 12 serial console port. In addition to Ethernet, the PON data center network 40 also supports RS-232 serial connectivity for console access.

As far as power consumption is concerned, a typical 48-port managed Gigabit Ethernet switch power consumption is around 50-60 W. The aggregation switch 22 that is required at EoR location in existing solution has additional power consumption. The integrated PON chassis power consumption is 40 W, thus offering power consumption savings in addition to rack space savings. The power consumption savings also correlate to reduced cooling requirements. Of course, as data centers have hundreds to thousands of racks, the savings from small reductions in space, power, cooling, cost, etc. multiply.

### ONU Chassis

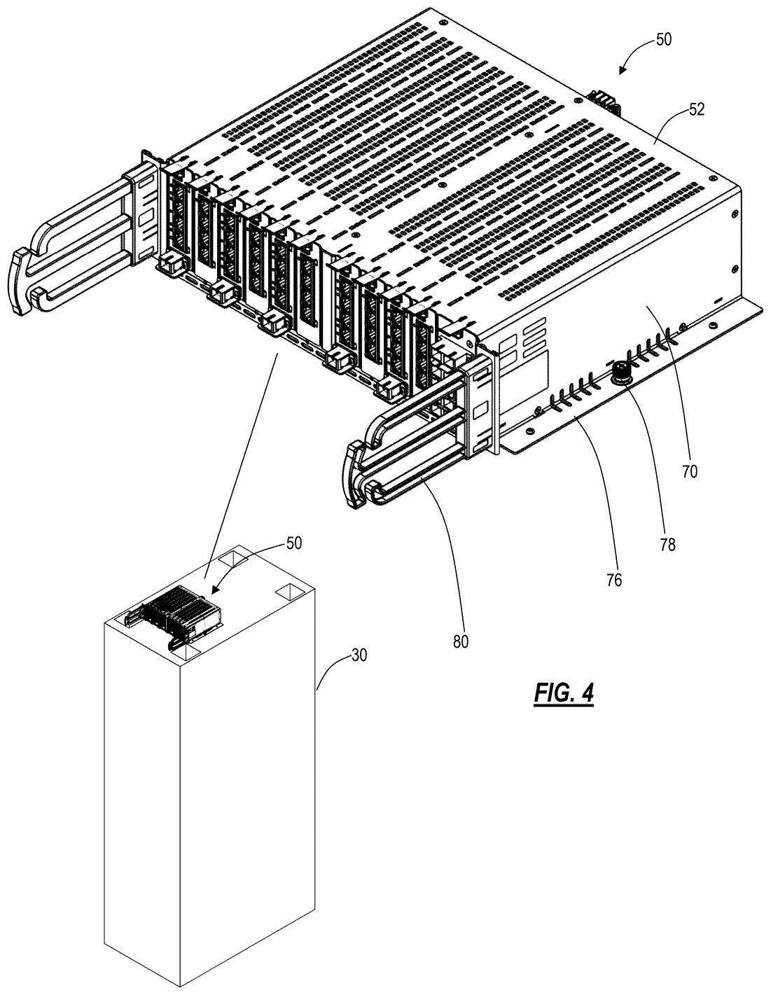

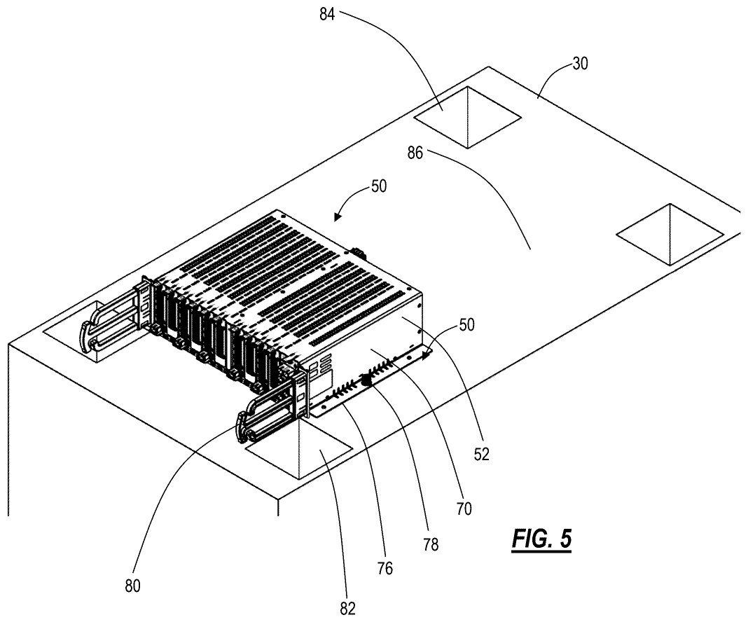

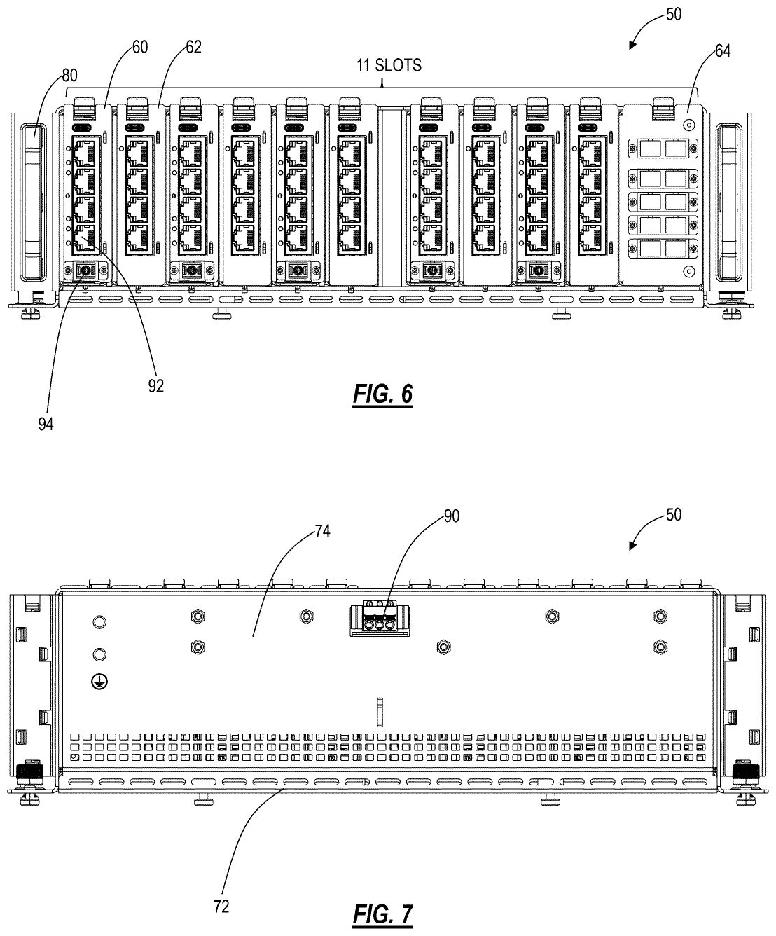

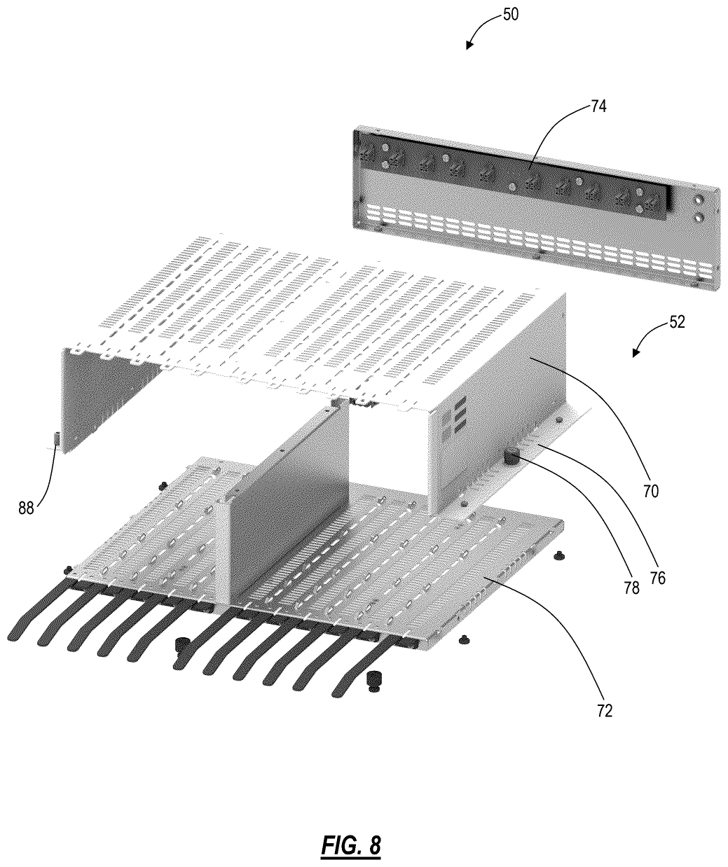

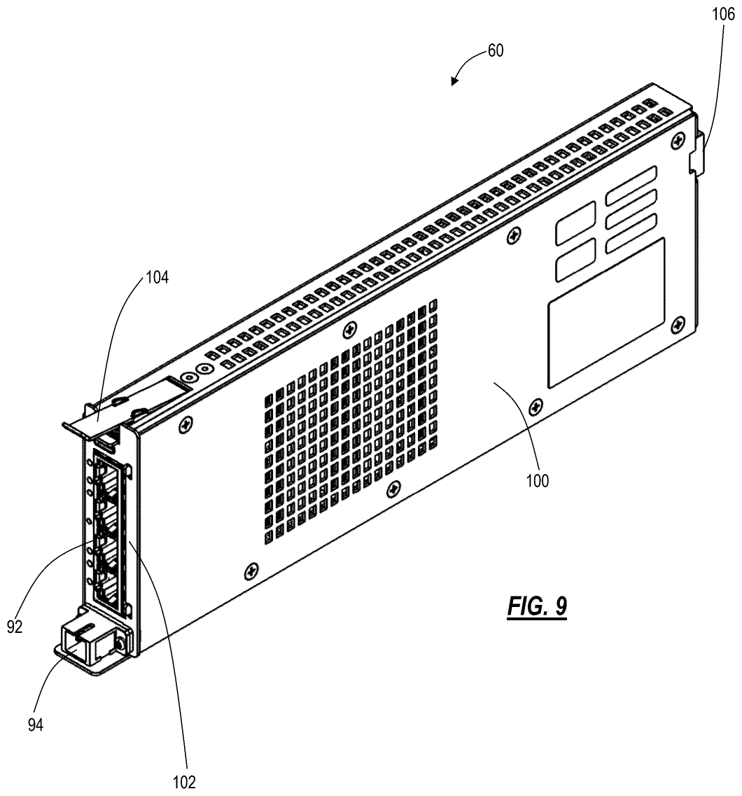

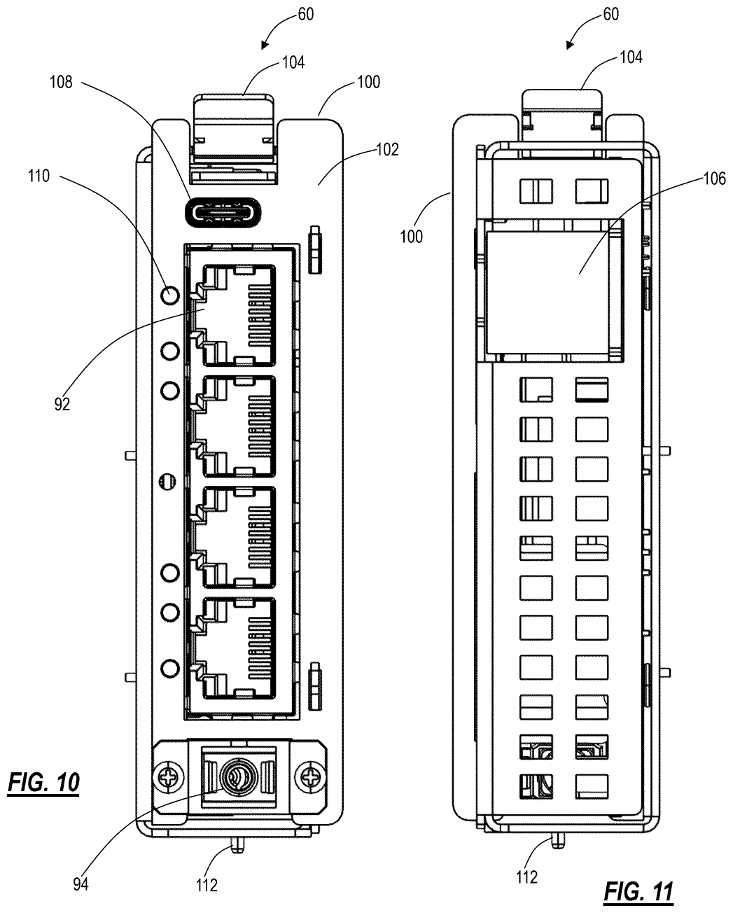

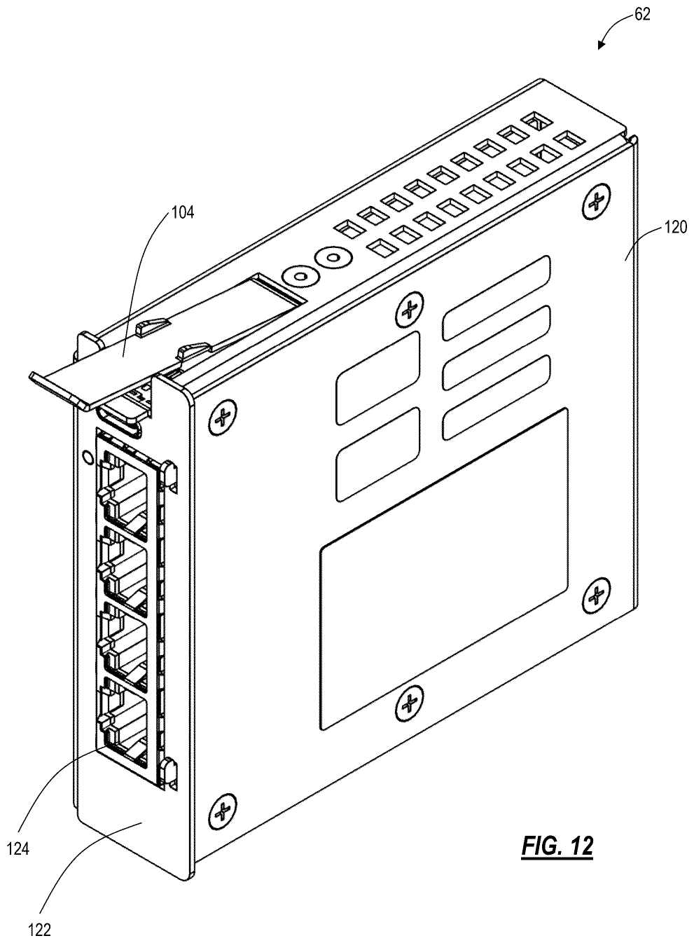

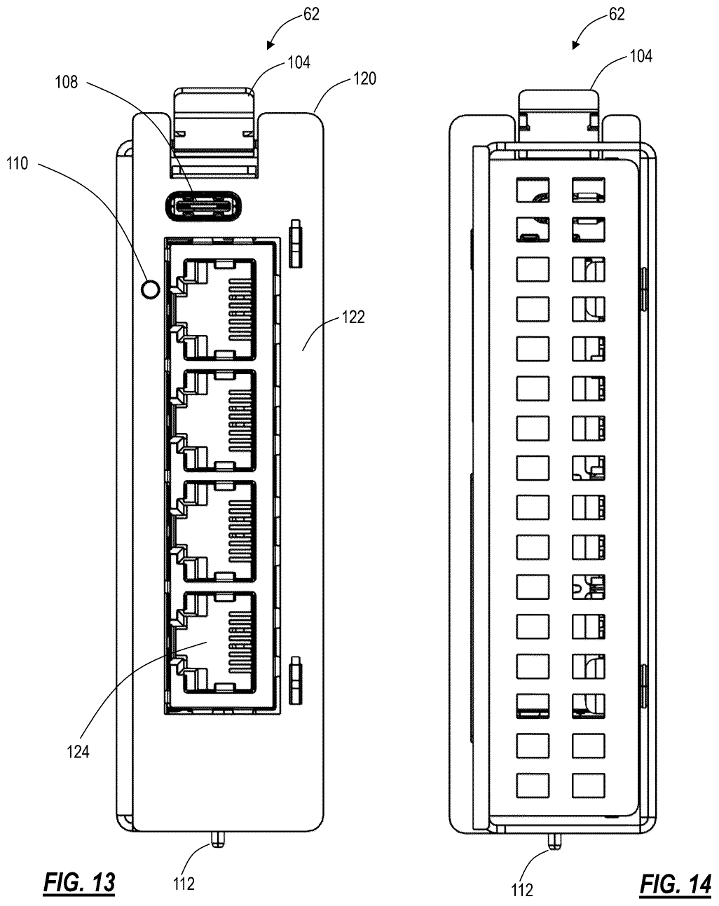

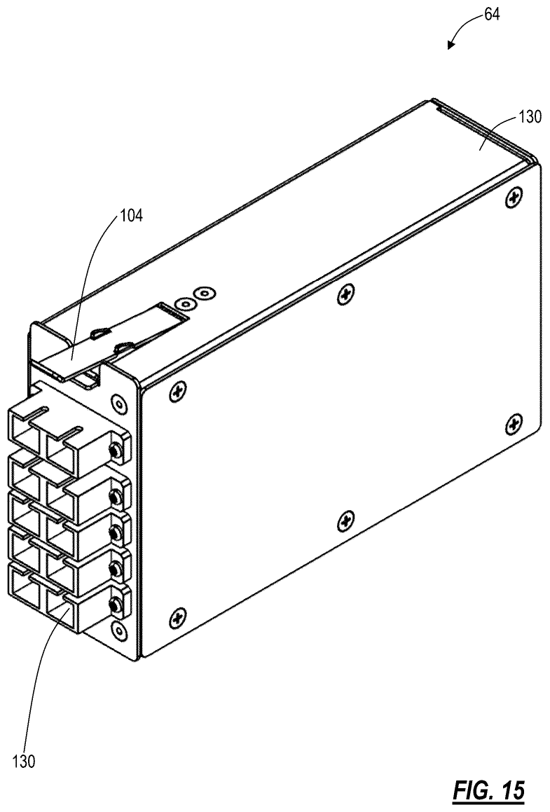

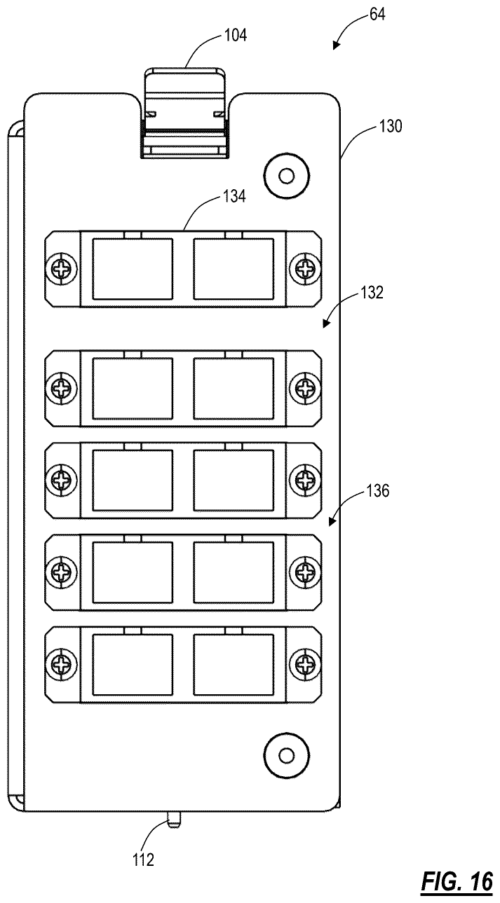

FIGS. 4-16 are various diagrams of the ONU chassis 50 and associated hardware. FIG. 4 is a perspective diagram of the ONU chassis 50 on the rack 30. FIG. 5 is a close-up perspective diagram of the top of the rack 30 with the ONU chassis 50 thereon. FIG. 6 is a front view of the ONU chassis 50. FIG. 7 is a rear view of the ONU chassis 50. FIG. 8 is an exploded view of a housing 52 of the ONU chassis 50. FIG. 9 is a perspective diagram of an ONU module 60. FIG. 10 is a front view of the ONU module 60. FIG. 11 is a rear view of the ONU module 60. FIG. 12 is a perspective diagram of a console module 62. FIG. 13 is a front view of the console module 62. FIG. 14 is a rear view of the console module 62. FIG. 15 is a perspective diagram of a fiber splitter 64. FIG. 16 is a front view of the fiber splitter 64.

Referring to FIGS. 4-8, the ONU chassis 50 includes the housing 52 that is configured to mount to the top of the rack 30. The ONU chassis 50 can be front access only. The housing 52 can include a cover 70, a base 72 disposed to the cover 70, and a power backplane 74 disposed to the cover 70 and the base 72. Collectively, the cover 70, the base 72, and the power backplane 74 form an enclosure with front openings to receive the modules 60, 62, and the fiber splitter 64, and with various openings for airflow. The modules 60, 62 are configured to connect to the power backplane 74 for power distribution. The housing 52 is configured to mount to a standard rack 30, e.g., a 19″ rack. To that end, the housing 52 can include a flange portion 76 which can support various keyhole standoffs 78.

Additionally, the housing 52 can include a cable routing guide 80 that extends from the front of the housing 52. In FIG. 5, the rack 30 can include openings 82 at the front of the rack 30 for cable entry from the servers 12 contained in the rack 30. The cable routing guide 80 can support cables from the openings 82. The rack 30 can also include openings 84 at the rear for cables as well, e.g., power. The openings 82 can be cutouts in the rack 30, as well as the rack 30 can be open. That is, the present disclosure contemplates any type of data center rack, including one that is fully enclosed like a cabinet, as well as one that is an open frame, as well as combinations. In FIG. 5, note the ONU chassis 50 does not take up the entire space on the top of the rack 30, and there is additional space 86 for additional equipment, such as a fiber tray, etc. For example, in an embodiment, the ONU chassis 50 can have a size of about 100×325×300 mm (H×W×D). Further, there can be an Electrostatic Discharge (ESD) plug 88 that grounds the ONU chassis 50 to the rack 30. The cover 70, the base 72, and the power backplane 74 can be formed from sheet metal or the like. The power backplane 74 can include a power input 90.

The ONU chassis 50 is configured to support field replaceable modules 60, 62, 64 in slots contained in the housing 52. Referring to FIG. 6, in an embodiment, the ONU chassis 50 is illustrated with 11 slots. Those skilled in the art will recognize other embodiments are possible and the 11 slots are merely presented for illustration purposes. In an embodiment, the first 10 slots, from left to right, are configured to each support one of the ONU module 60 or the console module 62, and the last slot, on the right is configured to support the fiber splitter 64. In the example of FIG. 6, the ONU chassis 50 is configured with five ONU modules 60, five console modules 62, and one fiber splitter 64. Here, this would support 40 servers 12 in a rack, i.e., each ONU module 60 has four Ethernet ports 92 and one optical port 94, with four×five=20 servers 12 and each console module 62 has four RS-232 ports 124, with four×five=20 servers 12. Of course, there can be additional ONU modules 60 to support more servers 12 over Ethernet. Again, this is merely presented for illustration purposes and other configuration of the slots between the modules 60, 62, 64 are contemplated.

### ONU Module

Referring to FIGS. 9-11, the ONU modules 60 are configured to support one or more ONUs in a module, with the Ethernet ports 92 connectable to end devices, namely the servers 12 in the PON data center network 40. The ONU module 60 includes a housing 100 configured to be inserted into the ONU chassis 50, such as in one of the slots. The housing 100 includes openings for air flow, a faceplate 102 with the ports 92, 94, a snap lock 104 for securing the ONU module 60 in the ONU chassis 50, and a power connector 106 on a rear side configured to mate with the power backplane 74. The faceplate 102 can include a Universal Serial Bus (USB) port 108 for connecting to a console module 62 to extend RS-232 ports for out of band management, as well as status indicators 110, such as Light Emitting Diodes (LEDs) to give port status. Also, the housing 100 can include a pin 112 that ensures proper insertion of the ONU module 60 into the ONU chassis 50, i.e., the pin 112 ensures the ONU module 60 is not inserted upside down.

Again, in an example embodiment, the ONU module 60 supports four ONUs, via four Ethernet ports 92, which can be RJ-45 ports that connect via Ethernet cables to the servers 12 in the rack. The four ONUs can communicate over 10 G PON via the optical port 94, which can be a single fiber with both transmit and receive on the same fiber. The optical port 94 from each of the ONU modules 60 in the ONU chassis 50 can be cabled to the fiber splitter 64 in the ONU chassis 50.

The ONU module 60 supports an integrated approach where multiple ethernet ports 92 (e.g., four in the ONU module 60) are supported in a single module or device with one optical port 94. The ONU module 60 combines the functionality of ONU, serving several end-users or networks, but connects to the OLT through a single fiber optic connection, via the optical port 94, which will be combined with all ONU modules 60 in the ONU chassis 50 via the fiber splitter 64 in the ONU chassis, as well as with the fiber splitters 44. The fiber splitters 44, 64 form the PON distribution network (i.e., tree).

In particular, due to the PON data center network 40 application, the ONU modules 60 can contain more than one Ethernet port 92 sharing the same optical port 94. For example, in a typical PON deployment, such as for residential Internet access, there is an ONU at each subscriber location, e.g., home, and there is one Ethernet port typically to one optical port. In the PON data center network 40, the end devices are the servers 12 all in the rack 30, so there can be multiple Ethernet ports 92.

This integrated approach can simplify network architecture, reduce hardware requirements, and improve manageability in certain PON deployments, such as the PON data center network 40. Of note, while the PON data center network 40 is one example application for the ONU chassis 50, those skilled in the art will appreciate other applications are possible, such as Multi-tenant Units. With Multi-tenant Units, in buildings with multiple tenants, such as apartment complexes or office buildings, a single integrated ONU module can serve multiple individual units. Each tenant's network can be segregated and managed independently, despite sharing a common physical infrastructure to the OLT.

### Console

Referring to FIGS. 12-14, the console module 62 is a management device for the ONU chassis 50. The console module 62 is used for initial setup, configuration, troubleshooting, and monitoring, e.g., the console module 62 can also be referred to as a console server. A console server in network equipment is a device that provides remote access to the console ports of other network devices, such as routers, switches, firewalls, and servers. This access is crucial for management, configuration, and troubleshooting, especially in environments where devices may not be easily accessible physically due to their location in data centers, remote sites, or secure environments.

The console module 62 includes a housing 120 configured to be inserted into the ONU chassis 50, such as in one of the slots. The housing 120 includes openings for air flow, a faceplate 122 with RS-232 ports 124, the snap lock 104 for securing the console module 62 in the ONU chassis 50, and the pin 112. The faceplate 102 can include a Universal Serial Bus (USB) port 108 for connecting to a console module 62 to extend RS-232 ports for out of band management, as well as status indicators 110, such as Light Emitting Diodes (LEDs) to give port status. In an embodiment, the console module 62 does not require power from the power backplane 74, but rather can receive power over one of the USB ports 108.

In an embodiment, the console module 62 can be used in conjunction with the ONU module 60, where the console module 62 is used for a management channel by and between the servers 12. For example, the servers 12 can support Ethernet, RS-232, and other types of connections for management. The ONU chassis 50 can support 10 or more slots, and there is not necessarily a need for 10×ONU modules 60 (i.e., 40 Ethernet ports) in a single rack. As such, some of the slots can house the console module 62 for supporting a management channel. In FIG. 6, e.g., there are 5 ONU modules 60, supporting 20 Ethernet ports, or servers 12 in a rack, and there are 5 console modules 62, e.g., support 20 RS-232 connections.

### Fiber Splitter

Referring to FIGS. 15-16, the fiber splitter 64 is a passive module configured to form a PON distribution network with other fiber splitters 64 in other ONU modules 60, connected to one another via the fiber splitter 44. The fiber splitter 64 includes a housing 130 configured to be inserted into the ONU chassis 50, such as in one of the slots, optical ports 132, the snap lock 104 for securing the fiber splitter 64 in the ONU chassis 50, and the pin 112.

The optical ports 132 can be designated as N:M ports where N ports 134 face the OLT 42, i.e., connect to the fiber splitter 44, and M ports 136 connect to each of the ONU modules 60 and their corresponding optical ports 84. In this example, N:M is 2:8. Here, there are possibly two ports 134, to support redundancy to connect to two OLTs, and eight ports 136 to support eight ONU modules 60 in the ONU chassis 50. Again, these are only presented for illustration purposes and different values are contemplated herein. Functionally, the fiber splitter 64 includes internal fiber components to divides the light signal from the N ports 134 to the M ports 136 evenly or unevenly, depending on the splitter design.

The connectivity between the OLT 42 and the ONU modules 60 is a tree where one OLT 42 (or dual OLTs 42 for redundancy) connect to every ONU module 60 via the same fiber tree. Those skilled in the art recognize PON includes various techniques to ensure only one ONU is communicating at a time to the OLT 42. In this configuration, it is one ONU module 60 at a time.

### Example PON Data Center Network

In an example, using the PON data center network 40 and the ONU chassis 50, assume a rack 30 includes 42RU and can accommodate 32 servers 12, and let's assume there are 16 racks 30 in a row in a data center as well as multiple rows. Each ONU chassis 50 will be in each rack 30 and connect to the fiber splitter 44 which can be a 1:16 splitter, so one XGS PON OLT link is split into 16 fibers. Each of the downstream port of the splitter goes into the ONU chassis 50, which is further split into eight links using the fiber splitter 64. Each of these eight links go to one ONU which has four UNI ports. Each server 12 would effectively get 1:512 of the total bandwidth connection to OLT. Average OLT bandwidth per Rack=8.7 Gbps/16=−544 Mbps. Of course, those skilled in the art will recognize the number of ONU modules to OLT can be variable, based on bandwidth needs and requirements. In this example, the PON data center network 40 can be used for a management network for the servers 12.

Other use cases are also contemplated, including a full replacement of the traditional data center network with the PON data center network. That is, the ONU chassis 50 and the same network architecture can be used for high-speed connectivity to the data center devices. The uplink from the ONU modules can use higher rate PON (e.g., 25G PON, 50G PON, 100G PON) to cater to the required higher bandwidth. Also, bandwidth is adjustable based on the ratio of ONUs to OLTs, and the inherent dynamic bandwidth allocation (DBA) algorithm to attain the maximum usage of bandwidth, which is part of PON to address bandwidth allocation. That is, using PON removes ToR, EoR switches in the data center.

### Power Consumption and Thermal Performance

The ONU chassis 50 can be a fanless design, with air cooling solely based on airflow through openings in the various housings.

### Chassis

In an embodiment, a chassis 50 includes a housing 52 configured to connect on top of a rack 30; a plurality of modules 60 that are selectively insertable in the housing 52, each of the plurality of modules 60 supporting one or more Optical Network Units (ONUs) or Optical Network Terminals (ONTs) for operation in a Passive Optical Network (PON); and a fiber splitter 64 configured to optically connect to each of the plurality of modules 60 and to a PON distribution network that connects to one or more Optical Line Terminals (OLTs) 42. The housing 52 can include a plurality of slots with each slot supporting one of a console module 62 or one of the plurality of modules 60.

Each of the plurality of modules 60 includes one or more Ethernet ports 92, each configured to connect to a device or server 12 in the rack 30; and an optical port 94 configured to connect to the fiber splitter 64. The one or more Ethernet ports 92 can include a plurality of Ethernet ports 92 on a corresponding module 60 for supporting a plurality of ONUs or OLTs on the corresponding module 60.

The housing 52 can include a power backplane 72 configured to connect to a power supply and to provide power to the plurality of modules 60. The housing 52 can include a flange 76 configured to attach to the top of the rack 30. The top of the rack 30 is above a plurality of servers 12 mounted inside the rack 30. The housing 52 is air cooled via a plurality of openings enabling airflow, and the chassis 52 can include a fanless design. The chassis 50 can include one or more cable routing guides connected to a front of the housing, wherein the rack includes one or more openings for cabling from devices mounted therein to the plurality of modules.

The fiber splitter 64 can include N:M optical ports, with N optical ports communicatively connected to the one or more OLTs 42 and M optical ports communicatively connected to corresponding optical ports 94 on the plurality of modules 60. The N optical ports are connected to a second fiber splitter 44 associated with one or more rows of racks with the second fiber splitter communicatively connected to the one or more OLTs.

In an embodiment, a data center network 40 include a plurality of the chassis 50. The plurality of the chassis 50 can provide a plurality of ONUs or ONTs, and the data center network 40 also includes the one or more OLTs 42 and one or more fiber splitters 44 in between the plurality of ONUs or ONTs and the one or more OLTs 42. Each ONU or ONT of the plurality of ONUs or ONTs can connect to a server 12 in a corresponding rack 30 associated with a corresponding chassis 50 for the ONU or ONT.

### Data Center Network

In another embodiment, a data center network includes X Optical Network Units (ONUs) or Optical Network Terminals (ONTs), X is an integer greater than one, each ONU or ONT is contained in a corresponding chassis that is configured to connect on top of a rack, and each ONU or ONT is configured to connect to a corresponding server in the associated rack; Y Optical Line Terminals (OLTs), Y is an integer greater than or equal to one; and a Passive Optical Network (PON) distribution network including one or more fiber splitters, the PON distribution network optical connects each of the X ONUs or ONTs to the Y OLTs.

The top of the rack can be above a plurality of servers mounted inside the rack. Each corresponding chassis can include a plurality of modules that connect to a plurality of servers mounted inside the rack, and an optical connection that connects to the PON distribution network from the rack. The X ONUs or ONTs with the Y OLTs operate in lieu of a Top of Rack (ToR) data center network and an End of Rack (EoR) data center network. The X ONUs or ONTs utilize PON techniques to connect the corresponding server to a carrier network.

The value of X is selected based on bandwidth requirements of a plurality of servers in the data center network. That is, the ratio of ONUs or ONTs to OLTs is selected based on the underlying bandwidth requirements of each server 12.

### CONCLUSION

It will be appreciated that the modules 60, 62 may include one or more generic or specialized processors (“one or more processors”) such as microprocessors; Central Processing Units (CPUs); Digital Signal Processors (DSPs): customized processors such as Network Processors (NPs) or Network Processing Units (NPUs), Graphics Processing Units (GPUs), or the like; Field Programmable Gate Arrays (FPGAs); and the like along with unique stored program instructions (including software and/or firmware) for control thereof to implement, in conjunction with certain non-processor circuits, some, most, or all of the functions of the methods and/or systems described herein.

Moreover, the modules 60, 62 may include a non-transitory computer-readable storage medium having computer-readable code stored thereon for programming a computer, server, appliance, device, processor, circuit, etc. each of which may include a processor to perform functions as described and claimed herein. Examples of such computer-readable storage mediums include, but are not limited to, a hard disk, an optical storage device, a magnetic storage device, a Read-Only Memory (ROM), a Programmable Read-Only Memory (PROM), an Erasable Programmable Read-Only Memory (EPROM), an Electrically Erasable Programmable Read-Only Memory (EEPROM), Flash memory, and the like. When stored in the non-transitory computer-readable medium, software can include instructions executable by a processor or device (e.g., any type of programmable circuitry or logic) that, in response to such execution, cause a processor or the device to perform a set of operations, steps, methods, processes, algorithms, functions, techniques, etc. as described herein for the various embodiments.

Although the present disclosure has been illustrated and described herein with reference to embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following claims. Further, the various elements, operations, steps, methods, processes, algorithms, functions, techniques, modules, circuits, etc. described herein contemplate use in any and all combinations with one another, including individually as well as combinations of less than all of the various elements, operations, steps, methods, processes, algorithms, functions, techniques, modules, circuits, etc.

What is claimed is:

1. A chassis comprising:
a housing configured to connect on top of a rack;
a plurality of modules that are selectively insertable in the housing, each of the plurality of modules supporting one or more Optical Network Units (ONUs) or Optical Network Terminals (ONTs) for operation in a Passive Optical Network (PON); and
a fiber splitter configured to optically connect to each of the plurality of modules and to a PON distribution network that connects to one or more Optical Line Terminals (OLTs).

2. The chassis of claim 1, wherein the housing includes a plurality of slots with each slot supporting one of a console module or one of the plurality of modules.

3. The chassis of claim 2, wherein the console module includes one or more RS-232 ports for supporting a plurality of console ports.

4. The chassis of claim 1, wherein each of the plurality of modules includes
one or more Ethernet ports, each configured to connect to a device in the rack; and
an optical port configured to connect to the fiber splitter.

5. The chassis of claim 4, wherein the one or more Ethernet ports include a plurality of Ethernet ports on a corresponding module for supporting a plurality of ONUs or OLTs on the corresponding module.

6. The chassis of claim 1, wherein the housing includes a power backplane configured to connect to a power supply and to provide power to the plurality of modules.

7. The chassis of claim 1, wherein the housing includes a flange configured to attach to the top of the rack.

8. The chassis of claim 1, wherein the top of the rack is above a plurality of servers mounted inside the rack.

9. The chassis of claim 1, wherein the fiber splitter includes N:M optical ports, with N optical ports communicatively connected to the one or more OLTs and M optical ports communicatively connected to corresponding optical ports on the plurality of modules.

10. The chassis of claim 9, wherein the N optical ports are connected to a second fiber splitter associated with one or more rows of racks with the second fiber splitter communicatively connected to the one or more OLTs.

11. The chassis of claim 1, wherein the housing is air cooled via a plurality of openings enabling airflow, and wherein the chassis includes a fanless design.

12. The chassis of claim 1, further comprising one or more cable routing guides connected to a front of the housing, wherein the rack includes one or more openings for cabling from devices mounted therein to the plurality of modules.

13. A data center network comprising:
X Optical Network Units (ONUs) or Optical Network Terminals (ONTs), X is an integer greater than one, each ONU or ONT is contained in a corresponding chassis that is configured to connect on top of a rack, and each ONU or ONT is configured to connect to a corresponding server in the associated rack;
Y Optical Line Terminals (OLTs), Y is an integer greater than or equal to one; and
a Passive Optical Network (PON) distribution network including one or more fiber splitters, the PON distribution network optical connects each of the X ONUs or ONTs to the Y OLTs.

14. The data center network of claim 13, wherein the top of the rack is above a plurality of servers mounted inside the rack.

15. The data center network of claim 13, wherein each corresponding chassis includes a plurality of modules that connect to a plurality of servers mounted inside the rack, and an optical connection that connects to the PON distribution network from the rack.

16. The data center network of claim 13, wherein the X ONUs or ONTs with the Y OLTs operate in lieu of a Top of Rack (ToR) data center network and an End of Rack (EoR) data center network.

17. The data center network of claim 13, wherein the X ONUs or ONTs utilize PON techniques to connect the corresponding server to a carrier network.

18. The data center network of claim 13, wherein the value of X is selected based on bandwidth requirements of a plurality of servers in the data center network.

19. The data center network of claim 13, wherein the corresponding chassis includes
a housing configured to connect on top of the rack;
a plurality of modules that are selectively insertable in the housing, each of the plurality of modules supporting one or more of the X ONUs or ONTs;
a plurality of modules that are selectively insertable in the housing, each of the plurality of modules supporting one or more of console ports; and
a fiber splitter of the one or more fiber splitters.

20. The data center network of claim 19, wherein each of the plurality of modules includes
one or more Ethernet ports, each configured to connect to a device in the rack; and
an optical port configured to connect to the fiber splitter.
